(19) United States
(12) Patent Application Publication
(10) Pub. No.: US 2019/0155366 A1
(43) Pub. Date: May 23, 2019

(54) CURRENT-SAVING STORAGE CONCEPT FOR ELECTRONIC MODULES IN A MOTOR VEHICLE (AS AMENDED)

(71) Applicant: Continental Automotive GmbH, Hannover (DE)

(72) Inventors: Hans-Michael Graf, Regensburg (DE); Martin Schramme, Königsbrunn (DE)

(21) Appl. No.: 16/300,256

(22) PCT Filed: May 16, 2017
(86) PCT No.: PCT/EP2017/061669

§ 371 Date: Nov. 9, 2018

(30) Foreign Application Priority Data
Jun. 15, 2016 (DE) 10 2016 210 661.9

(51) Int. Cl. G06F 1/3234; G06F 1/3225; G07C 5/08; G11C 5/14

(52) U.S. Cl. CPC G06F 1/3275; G11C 5/14; G07C 5/085; G06F 1/3225

(57) ABSTRACT

A device for storing electronic module data in a motor vehicle in a current-saving manner including: a first volatile memory area, supplied with current only if the electronic module is in normal operation, a second volatile memory area, supplied with current during normal operation and during a quiescent mode. A method for storing data of an electronic module in a motor vehicle in a current-saving manner includes: storing data in the second volatile memory area. The data are updated at least during the quiescent mode. Storing data in the first volatile memory area. The data in the first volatile memory area are not updated during the quiescent mode. Switching off the current supply of the first volatile memory area as soon as the electronic module leaves normal operation. Switching on the current supply of the first volatile memory area as soon as the electronic module is in normal operation.

### CROSS REFERENCE TO RELATED APPLICATIONS

This application is the U.S. National Phase application of PCT International Application No. PCT/EP2017/061669, filed May 16, 2017, which claims priority to German Patent Application No. 10 2016 210 661.9, filed Jun. 15, 2016, the contents of such applications being incorporated by reference herein.

### FIELD OF THE INVENTION

The invention relates to a current-saving storage concept for data of an electronic module in a motor vehicle.

### BACKGROUND OF THE INVENTION

Usually some electronic modules, such as sensors or control units in the vehicle, such as, for example, a battery sensor—for example an Intelligent battery sensor (IBS)—are constantly supplied with voltage from the onboard electrical network. Furthermore, the functional scope and thus the memory demand of all the electronic modules onboard a motor vehicle are constantly increasing. This concerns both volatile memories (RAM) and nonvolatile memories (EEPROM, Flash). Usually control units and sensors, such as, for example, a battery sensor, are intended to regularly measure and process further measurement data, for example data of the battery, even in the parked state of the vehicle.

In accordance with the prior art, the data of an electronic module are stored in a volatile memory even in the parked state of a motor vehicle. This has the disadvantage that the current demand of the electronic module exceeds the desirable limit value in the parked state of the vehicle since the volatile memories require a considerable operating current in order to maintain the data stored therein.

Alternatively, the data newly measured and calculated after each measurement are stored in a nonvolatile memory. Nonvolatile memories, by contrast, have no current demand in order to maintain the data stored therein. However, nonvolatile memories have the disadvantage that they allow only a small number of write operations or erase operations. Given a typical lifetime to be fulfilled of 15 years, under a realistic assumption that the measured and calculated data have to be written to a memory for example every 16 seconds, this results in a storage demand of 29.6 million write operations, which considerably exceeds the number of write operations allowed in the context of the technical specification for conventional nonvolatile memories. 100 000 write operations are typically regarded as allowed for conventional nonvolatile memories.

The electronic modules that are supplied directly from the vehicle battery even with the ignition switched off usually obtain information about the ignition position via a communication interface or, on the basis of the signals of the communication interface, can decide whether there is an intention to change to normal operation or to a quiescent mode. If the electronic module is a battery sensor, the decision as to whether there is an intention to change to normal operation or to a quiescent mode can also be taken by the battery sensor itself, for example on the basis of measurement values of the integrated measuring units.

Upon a change to the quiescent mode, components of the electronic module that are not required are deactivated or switched off or switched to a current-saving operating mode. As a result, the current consumption of the internal current supply of the electronic module decreases, said internal current supply in turn being supplied with electrical energy via the vehicle battery. It is also possible for a plurality of Internal current supplies to be present in an electronic module, for example in order to make different internal voltages (5 V, 3.3 V) available for specific functions. In the quiescent mode, some internal current supplies can also be entirely switched off.

By way of example, upon entry into the quiescent mode, a microcontroller can be switched off by the internal current supply being switched off. Thus, in accordance with the prior art, the volatile memory is automatically switched off as well. As long as the electronic module is in the quiescent mode, the microcontroller will be activated again cyclically or in an event-controlled manner and then decides whether the quiescent mode is continued or ended. In this case, the internal current supply Is activated again. If the quiescent mode is intended to be continued, the internal current supply is deactivated again.

Alternatively, upon a change into the quiescent mode, the microcontroller in accordance with the prior art can be stopped, without the internal current supply being switched off. In this case, the current consumption of the controller core decreases considerably in comparison with normal operation, but the volatile memory is maintained and consumes energy from the internal current supply that is in turn fed from the vehicle battery. Here, too, the microcontroller is activated again cyclically or in an event-controlled manner and then decides whether the quiescent mode is continued or ended. In order to calculate the decision about the continuation of the quiescent state, it is possible to read and/or update data from the volatile memory. It is also possible for measurement values available at this time to be processed and stored in the volatile memory.

In both cases, for the duration of the decision, the current consumption of the processor core rises momentarily to a level close to the current consumption in normal operation. In the first case the current consumption in the quiescent mode is lower than in the second case because the volatile memory is not permanently supplied with energy. In the second case, in return stored measurement values can be stored in the volatile memory and updated when required over the entire duration of the quiescent mode.

The cyclic or event-controlled activation of the microcontroller is triggered for example via one or more of the following events:
Reaching a preset value of a timer
Activity on the communication interface
A measuring device integrated in the control unit reports the reaching of preset threshold values

### SUMMARY OF THE INVENTION

An aspect of the invention is a storage concept for electronic modules in a motor vehicle which minimizes the current consumption of the electronic modules in the parked state of the vehicle in order to minimize the loading of the battery, and here at the same time enables a long lifetime of the memory.

An aspect of the invention is preferably based on the concept that at least two volatile memory areas are available for storing data of an electronic module in a motor vehicle. A first volatile memory area is supplied with current only if the electronic module is in normal operation. A second volatile memory area Is supplied with current during the normal operation and during a quiescent mode deviating from the normal operation.

In particular, the first volatile memory area is not supplied with current or energy during the quiescent mode.

The current supply during normal operation and during the quiescent mode deviating from normal operation means here that the supply is independent of the rest of the onboard vehicle electrical network, in particular the ignition position/terminal 15 of the onboard electrical network and takes place directly from the vehicle battery for example even with the vehicle switched off.

By way of example, the volatile memory area can be a “Random Access Memory” (RAM).

In this case, by way of example, an electronic module connected to an onboard electrical network of a vehicle can be involved. By way of example, the electronic module can be a control unit or a battery sensor, in particular an intelligent battery sensor.

The electronic module is in at least two states, normal operation and the quiescent mode, during the lifetime of the vehicle. During normal operation, the electronic module has a higher functionality and a greater storage demand, wherein a higher current consumption of the electronic module is permissible. By way of example, the electronic module can be in normal operation with the engine running. By way of example, the electronic module can be in normal operation with the generator running. During the quiescent mode, the electronic module has a lower, functionality and a lower storage demand, wherein a lower current consumption of the electronic module is desired. By way of example, the electronic module can be in the quiescent mode with the generator switched off. By way of example, the electronic module can be in the quiescent mode with the engine switched off. In addition, the electronic module can have even further modes; by way of example, the electronic module can be in a switched-off state. The switched-off state can occur for example when the battery Is demounted or is defective. While the electronic module changes from one state to another state, the electronic module is in a transition mode. Accordingly, during the lifetime of the vehicle the electronic module changes at least from the states of normal operation to the quiescent mode and from the quiescent mode to normal operation. If the electronic module is in further states, such as the switched-off state, for example, during the lifetime of the vehicle, further transition modes are accordingly necessary. The state of normal operation also includes, in particular, any state changes that leave normal operation. The state of normal operation should be understood also to mean, in particular, any state changes for which the electronic module is in normal operation after the state change.

The second volatile memory area Is supplied with current even with the vehicle parked and serves to store measurement data and the values processed therefrom, which have to be updated at short time intervals even during the quiescent phase.

Besides the two volatile memory areas, the device can comprise a nonvolatile memory area. By way of example, the nonvolatile memory area can be an “Electrically Erasable Programmable Read Only Memory” (EEPROM) or a Flash EEPROM.

In particular, the first volatile memory area can be operated and/or switched off separately from other memory areas, in particular separately from the second volatile memory area. In particular, the second volatile memory area can be operated and/or switched off separately from other memory areas, in particular separately from the first volatile memory area. What is conceivable in this case is memory areas on one data memory, wherein the memory areas can be operated and/or switched off separately, and also a plurality of data memories which can be operated and/or switched off separately.

By way of example, the two volatile memory areas can have a different size. By way of example, the memory size of the second volatile memory area can be smaller than the memory size of the first volatile memory area. Since the first volatile memory area is not supplied with current during the quiescent phase, the energy saving is particularly great since the energy consumption of a volatile memory depends on the memory size thereof.

By way of example, the quiescent current demand in the quiescent mode of the electronic module can be below 100 μA. It is often an aim for the electronic module, for example a battery sensor, to require a least possible quiescent current demand in the quiescent mode. By virtue of the memory areas that are able to be switched off and/or operable separately, the quiescent current demand of the electronic module is reduced to a value of below 100 μA since only the second volatile memory area is permanently supplied with current.

An aspect of the invention furthermore relates to a method for using the above-described device for a current-saving storage concept. Data that are updated at least during the quiescent mode of the electronic module are stored in the second volatile memory area. Data that are not updated during the quiescent mode of the electronic module are stored in the first volatile memory area. The current supply of the first volatile memory area is switched off as soon as the electronic module leaves normal operation. Accordingly, the current supply of the first volatile memory area is switched off, for example, as soon as the electronic module is in the quiescent mode. The current supply of the first volatile memory area Is switched on again as soon as the electronic module is in normal operation. Accordingly, the current supply of the first volatile memory area is switched on again, for example, as soon as the electronic module has left the quiescent mode in the direction of normal operation.

As soon as the electronic module leaves normal operation, by way of example, the data of the first volatile memory area are copied into the nonvolatile memory area. The current supply of the first volatile memory is only switched off after the copying is concluded. Accordingly, the copying is concluded before the electronic module leaves the transition mode from normal operation, that Is to say the electronic module enters the quiescent mode, for example. This prevents a data loss of the data stored on the first volatile memory. By virtue of the fact that a write operation of the nonvolatile memory takes place only when the electronic module leaves normal operation, the number of write cycles of a nonvolatile memory that are typically allowed in the context of the technical specification is not exceeded.

After the current supply of the first volatile memory has been switched on again, by way of example, the data previously copied into the nonvolatile memory area are copied back into the first volatile memory area. Accordingly, the copying operation takes place for example during the transition mode between the quiescent mode and normal operation.

In order to carry out the method described above, the device can comprise a control device that is configured accordingly.

### BRIEF DESCRIPTION OF THE DRAWINGS

One possible exemplary embodiment of the invention is described in greater detail below with reference to the drawings. However, the invention is not restricted to this exemplary embodiment. In the figures here:

FIG. 1: shows an electronic module in normal operation

FIG. 2: shows an electronic module in the quiescent mode

### DETAILED DESCRIPTION OF THE PREFERRED EMBODIMENTS

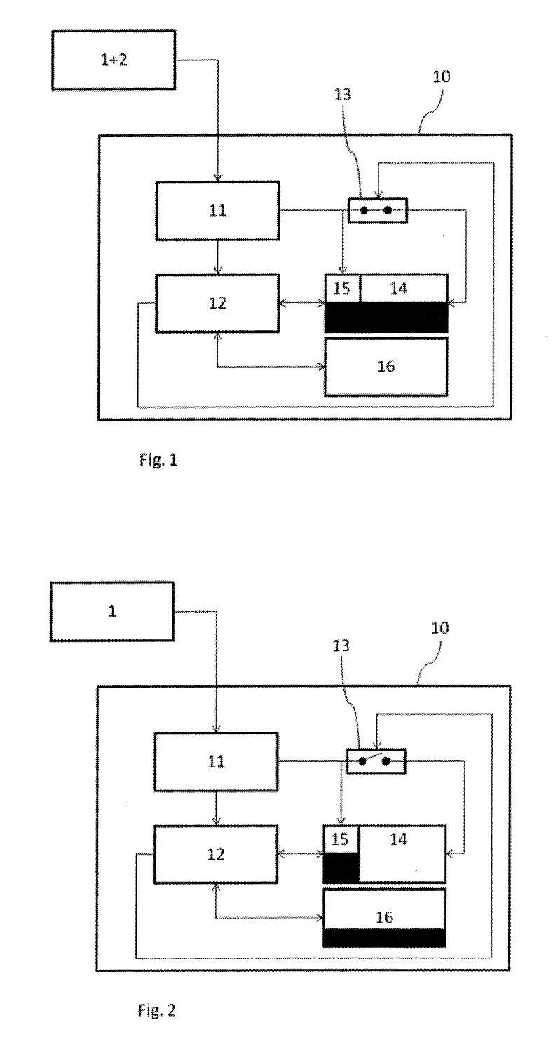

In FIG. 1, the electronic module is supplied with energy by a battery and a generator via an onboard electrical network. The electronic module has an internal current supply, which supplies the first volatile memory area, the second volatile memory area and the microcontroller with energy from the onboard electrical network. The switch, which can be opened and dosed by means of a control signal of the microcontroller, is dosed in FIG. 1. Therefore, the first volatile memory area is supplied with current in FIG. 1. The black area in the volatile memory areas represents the fact that the first and second volatile memory areas are used for storing data or updating the latter during normal operation of the electronic module. The nonvolatile memory area is not used during normal operation of the electronic module in FIG. 1. In this exemplary embodiment, the first and second nonvolatile memory areas are part of a memory chip, wherein the first and second nonvolatile memory areas can be switched off and/or operated separately.

In FIG. 2, the electronic module is supplied with energy by a battery via an onboard electrical network, for which reason the electronic module is in the quiescent mode. The switch is open in FIG. 2; therefore, the first volatile memory area is not supplied with energy. During the quiescent mode, as Illustrated in FIG. 2, the second volatile memory area and the nonvolatile memory area are used for storing data. While the electronic module transitions from normal operation to the quiescent mode, the data of the first volatile memory area are stored in the nonvolatile memory area. While the electronic module transitions from the quiescent mode to normal operation, the data of the nonvolatile memory area are copied back into the first volatile memory area.

1. A device for storing data of an electronic module in a motor vehicle comprising:
a first volatile memory area, which is supplied with current only if the electronic module is in normal operation, and
a second volatile memory area, which is supplied with current during normal operation of the electronic module and during a quiescent mode of the electronic module, said quiescent mode deviating from the normal operation.

2. The device as claimed in claim 1, wherein the device additionally comprises a nonvolatile memory area.

3. The device as claimed in claim 1, wherein the first volatile memory area can be operated and/or switched off separately from the second volatile memory area.

4. The device as claimed in claim 1, wherein the second volatile memory area can be operated and/or switched off separately from the first volatile memory area.

5. The device as claimed claim 1, wherein the memory size of the second volatile memory area is smaller than the memory size of the first volatile memory area.

6. The device as claimed in claim 1, wherein a quiescent current demand during the quiescent mode of the electronic module is below 100 μA.

7. The device as claimed in claim 1, wherein the electronic module is a battery sensor.

8. A method for storing data of an electronic module in accordance with a device as claimed in claim 1 comprising:
Storing data in the second volatile memory area, wherein the data stored in the second volatile memory area are updated at least during the quiescent mode of the electronic module;
Storing data in the first volatile memory area, wherein the data stored in the first volatile memory area are not updated during the quiescent mode of the electronic module;
Switching off the current supply of the first volatile memory area as soon as the electronic module leaves normal operation; and
Switching on the current supply of the first volatile memory area as soon as the electronic module is in normal operation.

9. The method as claimed in claim 8, further comprising copying the data of the first volatile memory area into a nonvolatile memory area as soon as the electronic module leaves normal operation, wherein the current supply of the first volatile memory area is only switched off when the copying is concluded.

10. The method as claimed in claim 9, further comprising copying the data that have previously been copied into the nonvolatile memory area back into the first volatile memory area after the current supply of the first volatile memory area has been switched on again.

11. The device as claimed in claim 1, wherein the device comprises a control device configured to carry out a method comprising:
storing data in the second volatile memory area, wherein the data stored in the second volatile memory area are updated at least during the quiescent mode of the electronic module;
storing data in the first volatile memory area, wherein the data stored in the first volatile memory area are not updated during the quiescent mode of the electronic module;
switching off the current supply of the first volatile memory area as soon as the electronic module leaves normal operation; and
switching on the current supply of the first volatile memory area as soon as the electronic module is in normal operation.
